(19) United States
(12) Patent Application Publication
(10) Pub. No.: US 2008/0248320 A1
(43) Pub. Date: Oct. 9, 2008

(54) Coating for Parts Made of Titanium or the Alloy Thereof or Preventing Cold Welding

(75) Inventors: Fred-Rainer Grohmann, Urdorf/LH (CH); Michael De Wild, Oberwil (CH); Marcello Memmolo, Sissach (CH)

Correspondence Address: SCULLY SCOTT MURPHY & PRESSER, PC, 400 GARDEN CITY PLAZA, SUITE 300, GARDEN CITY, NY, 11530, US

(73) Assignee: STRAUMANN HOLDING AG, BASEL (CH)

(21) Appl. No.: 12/065,430

(22) PCT Filed: Aug. 9, 2006
(86) PCT No.: PCT/EP2006/007872

§ 371 Date: May 7, 2008

(30) Foreign Application Priority Data
Sep. 1, 2005 (EP) 050190537

(51) Int. Cl. C23C 14/34; B32B 15/04

(52) U.S. Cl. 428/457; 204/192.15

(57) ABSTRACT

The invention refers, among others, to a PVD method for the coating of elements made of titanium or titanium alloy to prevent cold welding. This method includes at least the following steps:
a) positioning the elements in a recipient,
b) application of a vacuum,
c) deposition of a first metal or a first metal alloy in nitrogen and acetylene atmosphere,
d) deposition of a second metal or a second metal alloy in nitrogen and acetylene atmosphere,
e) repetition of steps c) and d) until a sufficient layer thickness is achieved,
f) ventilation of the recipient,
g) removal of the elements from the recipient,
h) purification of the elements with a suitable cleansing bath.

### INTRODUCTION

The present invention refers to elements made of titanium or titanium alloy in the area of medical and medicinal technology, such as bone screws, implants, dental implants, transmission parts, (bone) plates, implanting aids or tools such as tweezers, burs etc. made of titanium or titanium alloy which come in contact with other elements made of titanium or titanium alloys.

Screw implants are screwed into a bore prepared in the bone or jaw bone, respectively, or have a self-tapping outside thread which, when screwed into a prepared bore, creates the inside thread itself. Cylindrical implants, on the contrary, have no outside thread and are pressed into a bore prepared in the bone. The present invention refers mainly to enossal dental implants in screw form.

The purpose of transmission parts is to keep implants stable in the packaging during transport and storage, to allow grasping, removal and screwing of the implant into the pre-bored hole in the bone. For handling of the aforementioned implants, several adapters and transmission parts, respectively, are known. For the storage of such implants, ampules of different forms, which are used for sterile storage, are on the market.

From WO-A1-98 55039, a rotationally symmetrical transmission part for an implant to be inserted into a bone, in particular a dental implant, and an inner ampule or ampule for storage of the implant are known, wherein the transmission part can be screwingly engaged with the implant by means of a bolt barrel. The unit, consisting of the transmission part and the implant screwed thereon, can be placed into an inner ampule for storage and transport of the implant, which ampule has a fixing portion in which the transmission part can be mounted directly or indirectly and which has a lateral recess, corresponding to the length of the unit, through which the implant with the transmission part can be removed. The prior art transmission part has at the end opposed to the bolt barrel an extension with an external polyhedron (particularly an octagon), onto which a tool, e.g. a screwing tool, is pluggable. A securing element, preferably an O-ring, is provided in a radial groove beneath the extension. In addition, according to WO-A1-98 55039, an outer capsule having a cover to be screwed thereon is adapted such that the transmission part with the implant can be arrested axially between the bottom of the outer capsule and the cover. The total content of WO-A1-98 55039 is hereby incorporated by reference.

U.S. Pat. No. 6,247,932 disclosed a container for a dental implant wherein the transmission part is engagingly connected to the implant. Analogously to the outer capsule of WO-A1-98 55039, the well-known container is adapted to receive and secure the transmission part with the snapped-on implant. In addition, U.S. Pat. No. 6,247,932 provides means for securing the implant against rotation with reference to the transmission part and means for force transmission from the transmission part to the implant, respectively.

A transmission part with a snap-on mechanism is known from U.S. Pat. No. 6,206,696, where the connection to the implant takes place by means of snapping into a healing screw. Similar transmission parts are known from WO-A1-00 2496 and WO-A1-01 50978, which can be connected by a snapping process to a healing screw attached to the implant.

Transmission parts are either screwed to the implant or mounted in or onto the implant, respectively. The disadvantage of screwed transmission parts is that they are released from the implant head by grasping of the transmission part with a counter wrench—while simultaneously the freshly placed implant is fixed by a second wrench—, and thus carefully released. In particular with dental implants—within the restricted space of a patients mouth with existing neighboring teeth, particularly in the anterior area—, these operations with two instruments require high manual dexterity of the operating surgeon, are therefore always difficult and time-consuming. In case of changing positions of the placed implants, in particular in the upper and lower jaws, it can also be problematic to immediately recognize the releasing direction when the adapter is removed. New solutions therefore work with a snap-on connection which is easier to release.

In certain cases, it is advantageous to not store the implant with pre-assembled transmission part dry, as usual, but in a liquid, such as water or a saline solution. This is necessary, for example, if the surface of the implant is particularly refined (by coating with peptides, lipids or proteins), so that storage in a suitable liquid is necessary. This also applies, for instance, to a hydrophilic surface such as is described in EP 1150620. The hydrophilicity, charge, chemical activity and chemical purity of the surface are protected against atmospheric impurities, such as carbon dioxide or hydrocarbons, if the implant is stored in pure water with selected additives, if applicable.

After the storage of implants with transmission parts mounted on them, in particular after storage in an aqueous environment (e.g. in an iso-osmotic sodium chloride solution), it was surprisingly found that the two elements could no longer be separated from each other. Apparently, in this case, “cold welding” of the two elements, each consisting of titanium or of a titanium alloy, which should actually be protected by the titanium oxide layer which automatically forms on the titanium surface, takes place. During storage of the assembled elements, probably an instantaneous re-oxidation (e.g. in case of a scratch/damage to the protective titanium oxide layer) or further development of the oxide layer takes place on the titanium surface, due to which the two elements are firmly attached to each other and can no longer be separated. This process is greatly accelerated in case of storage in water or aqueous solutions.

The cold welding effect is already known for implants made of titanium. The implant manufacturer Zimmer even makes positive use of cold welding—all AdVent implants have a hexagon socket connection with friction adaptation. During this process, hexagon sockets with assemblies which are fit by friction are intentionally subjected to cold welding with the implant, by which process micromotions are fundamentally removed and the connection becomes free of gaps and bacteria-proof (product catalog January 2004 of Zimmer Dental GmbH). In such case, the cold welding effect is advantageous and desirable. If; however, the titanium containing elements are to be separated again after the implantation, cold welding is very problematic. If e.g. cold welding between the bone screws and the metal plate for osteosynthesis takes place, they can no longer be released from the plate during removal of the osteosynthesis material, even with maximum effort, and corresponding substitute techniques, generally of sheer force, are necessary. Also if transmission parts for implants are used, it must be guaranteed that they can be separated from each other without any problems after the implantation.

An obvious solution are surface treatments or coatings to form a protective or interlayer between the two titanium elements (of pure titanium or of a titanium alloy). Such treatments prevent cold welding of the elements, simultaneously promoting the tribological properties such as sliding behavior and drier lubrication. The protective or interlayer should be firmly attached, inert during storage in liquids such as water or aqueous saline solutions and biocompatible. It is important that the layer be inert, i.e. insoluble in the liquid, since otherwise the surface of the implant could be contaminated or altered. Possible surface treatments are e.g. trovalizing, mechanical polishing, electro-polishing, anodizing or blasting with glass beads, steel beads, titanium oxide or laser. Coatings with gold, diamond (ADLC—amorphous diamond-like carbon) or metal nitrides, such as zirconium nitride, titanium nitride, chromium nitride, tungsten nitride or titanium aluminum nitride, are possible. These possibilities were tested, but did not lead to an improvement of cold welding and were therefore rejected.

It is therefore an object of the present invention to propose a coating which is applied on an element made of titanium or titanium alloy, in particular a transmission part, so that after assembly on a second element made of titanium or titanium alloy, in particular an implant, and after storage of the two assembled elements in a liquid, both elements can be separated from each other without any problem, i.e. manually or without further tools, respectively, e.g. after implantation in a bone. A separation should also be possible after the application of force (e.g. screwing in with torsional load between the two elements). This coating should have low abrasion and be such that it does not influence or alter the geometrical and surface properties and the biocompatibility of the two elements.

According to the invention, this aim and object is achieved by means of a coating according to claim 8 and by means of a method for its production according to claim 1. The invention further concerns coated elements according to claim 7, made of titanium or titanium alloy, which are employed in medical engineering.

The invention is based on a PVD method for the coating of elements made of titanium or titanium alloy, including at least the following steps:
a) positioning of the elements in a recipient,
b) application of a vacuum,
c) deposition of a first metal or a first metal alloy in nitrogen and acetylene atmosphere,
d) deposition of a second metal or a second metal alloy in nitrogen and acetylene atmosphere,
e) repetition of steps c) and d) until a sufficient layer thickness is achieved,
f) ventilation of the recipient,
g) removal of the elements from the recipient,
h) cleaning of the elements with a suitable cleansing bath.

In addition, a pretreatment of the surface can be performed after step b), particularly by sputtering with noble gases. Also, the ratio—in particular linear—of nitrogen and/or acetylene can be altered during step e). It is further particularly preferred that the layer is at least 1 μm thick. The method according to the invention, in which the first metal or the second metal are chromium and/or the first metal or the second metal are zirconium, are particularly preferred.

This application concerns a coating, manufactured with the method according to the invention, as well as to elements made of titanium or titanium alloy with a coating manufactured with the method according to the invention. This applies particularly to implants, dental implants, bone screws or transmission parts. The invention further concerns a combination of elements, where at least one element is at least partially provided with an inventive coating.

The layer according to the invention consists of different individual layers made of at least two different metals. Manufacturing of the layer is performed by means of vacuum deposition of different individual layers made of at least two different metals.

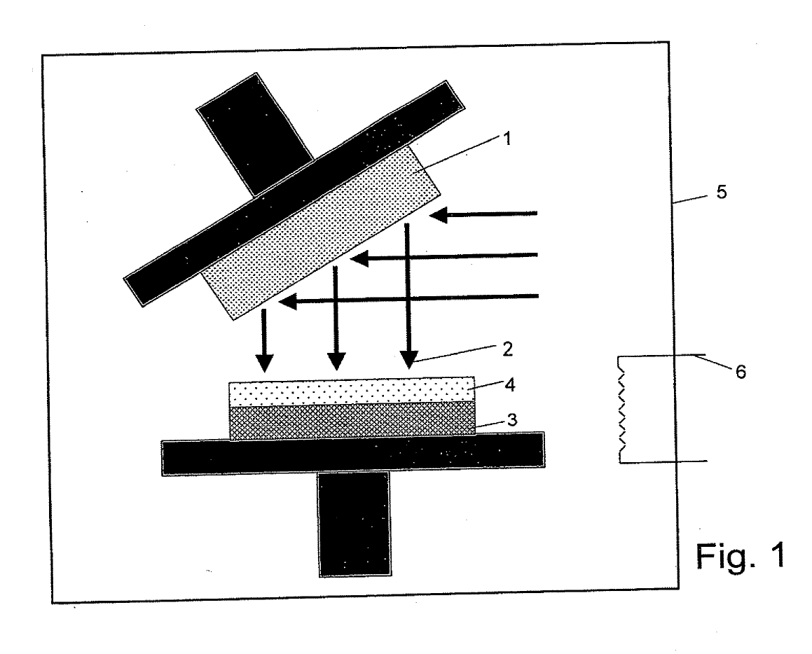

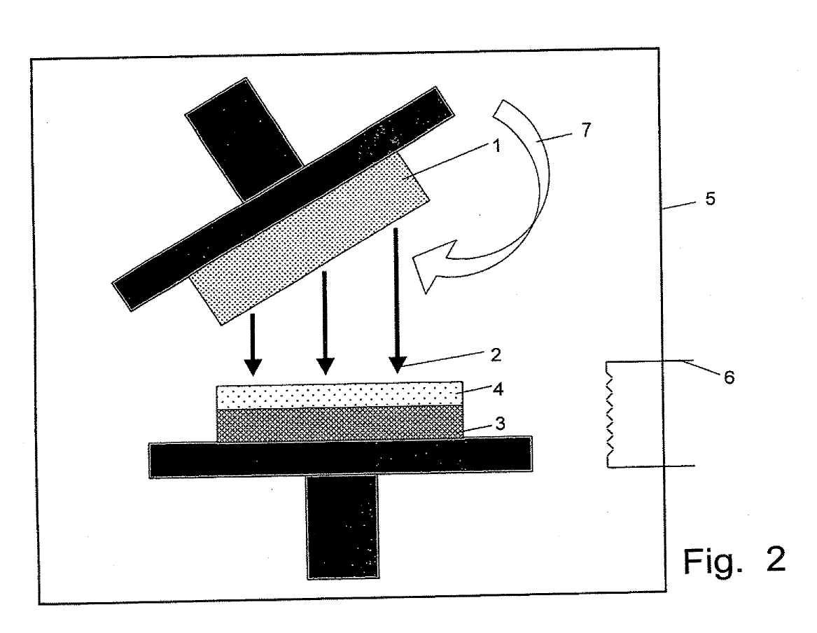

Manufacturing takes place by means of the PVD method (Physical Vapor Deposition). This method is schematically shown in FIG. 1. In a vacuum chamber 5, a vapor 2 is generated by sublimation (or boiling) of a solid (or molten) material source or target 1. The vapor atoms or molecules move from the source to the substrate 3 and condensate there to form a solid film 4. Different vapor deposition techniques differ in the way the evaporator material is heated: arc method, electron beam method, laser method, molecular-beam epitaxy and thermal method. The arc evaporation is a special form of vapor deposition (see FIG. 2). Between the anode and the target switched as the cathode (starting material) 1, an arc 7 is struck which “travels” on the cathode surface. Where the arc strikes the target, the material is converted to the gaseous state 2 and ionized to a large percentage due to the high currents and power densities. The gas and the ions strike the substrate 3 and lead to layer formation 4.

Before the elements to be coated can be provided with a coating, they must be absolutely free from fat and microscopically clean, dry and free from any oxides. With the coating according to the invention, this preliminary cleaning can take place e.g. by means of a 12-chamber ultrasonic cleaner. Subsequently, the pretreated elements are placed in a recipient (coating plant) 5 and fastened to special supports stable enough for a double or triple rotation. After the doors have been closed, the recipient is evacuated until there is a final vacuum of at least 1.0×10⁻⁶ mbar. To reach this vacuum, e.g. turbo-molecular pumps are used.

During coating, it is an advantage if the elements or substrates to be coated have a certain temperature, e.g. approximately 200° C., in order to ensure better adhesion to the surface by epitaxial growth. However, the initial temperature to be set for the substrate or the part to be coated, respectively, depends on the material of the element to be coated and can therefore vary or deviate from the value mentioned above. The initial temperature can be controlled in the plant, e.g. by means of an electronic infrared heater 6, which is normally possible within a range of approximately 80° C. to approximately 500° C. For the coating according to the invention, the content of the recipient is heated to approximately 200° C.-250° C.

Then the titanium oxide layer which has automatically formed on the surface of titanium and titanium alloys can be removed partially or completely, since it can reduce or even prevent the adhesion of the coating. Due to the applied vacuum within the recipient 5, an immediate re-formation of the oxide layer is prevented and the surface is thus perfectly prepared for the subsequent coating process. This preparation of the surface can take place by firing of a plasma cleaning process with very high voltage (500-1400 V) in a vacuum. During this process, the surface is bombarded with metal ions of very high energy (triple sound velocity; ion etching). This is done with such force that the ions do not adhere to the surface. In addition, (a small amount of) noble gas (e.g. neon or argon) is let in through a valve 14 so that the sputtered ions can be better aspirated. However, a preparation of the surface is also possible by dry etching or RIE (reactive ion etching).

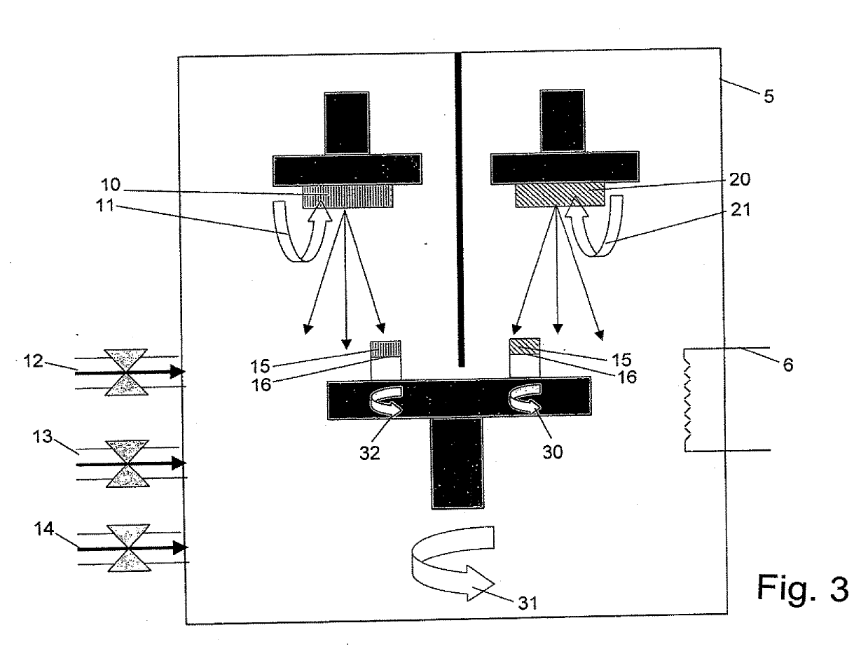

Subsequently, the actual coating takes place (see also FIG. 3). The coating according to the invention is now performed by the alternating firing of different metal targets 10 and 20. Particularly preferred is the alternating firing of a target made from pure zirconium and a target made from pure chromium; but basically, other metals such as gold, silver, iron, titanium, niobium, hafnium or a suitable alloy are possible. In this manner, a vapor-deposited “sandwich structure” or “layer by layer” is produced. The procedure is performed with at least two different metal targets; however, procedures in which more than two metals or metal alloys are deposited are suitable as well. Particularly preferred are coatings made of two or more metal targets where the ratio of the first metal or the first metal alloy to the total amount of metal in the coating is between 30 and 70 atomic percent, particularly between 40 and 60 atomic percent, particularly preferred between 45 and 55 atomic percent.

On a metal plate (target) 10 which consists e.g. of purest zirconium, an arc 11 is fired which at some points has approximately 6,000° C. The target is cooled from the rear side to prevent it from melting, for it should never exceed a temperature of 250° C. The dissolved metal ions are now again accelerated by means of a bias voltage (negative voltage) and “welded” onto the surface 14 to be coated. While traveling from the target to the part to be coated, the metal ion now takes up one nitrogen molecule (N₂) which is made available in the recipient during coating. Analogously, a second arc 21 is fired on a second target 20 which consists e.g. of purest chromium. By assembly of the elements to be coated on a rotating plate 30, the sandwich structure described above is produced. To achieve complete and even coating, not only the plate is rotated 31, but also the assembled elements themselves 32. In a large coating plant, a triple rotation should be guaranteed.

The starting vacuum has less than 10⁻⁵ mbar, preferably approximately 2.0×10⁻⁶ mbar. During subsequent coating of the substrate, the vacuum is reduced by inlet of gases such as nitrogen 12 or acetylene 13 and normally levels out at a value range of approximately 10⁻² to 10⁻³ mbar. The starting point can be e.g. pure nitrogen, pure acetylene or a mixture of nitrogen and acetylene, metal nitrides, carbides and/or carbonitrides being deposited accordingly.

According to a preferred embodiment of the method according to the invention, the composition of the gas is altered during coating so that the composition of the coating is altered during the coating process as well. According to the preferred embodiment, nitrides are initially deposited. In addition to nitrogen, carbon in the form of acetylene is now let in, increasingly causing carbonitrides to be deposited in the layer. The carbon ratio preferably increases linearly, i.e. acetylene gas is increased from an initial concentration within the order of approximately 0-1% to approximately 30-35%, the portion of carbonitrides in the coating increasing accordingly.

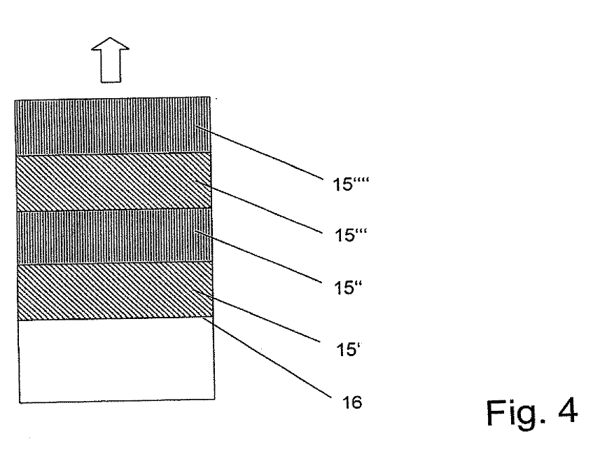

Due to the fact that the layer almost has an atomic structure, a “growth rate” of the coating of approximately 0.5 μm per coating hour is to be expected. One coating process 15 takes up to several hours from closing of the recipient's door to reopening it, depending on the thickness of the layer. FIG. 4 schematically illustrates that the coating according to the invention consists of several individual layers 15′, 15″, 15″′, 15″″ etc.; in total, this results in up to 200 individual layers, deposited on the surface 16 of the respective element.

One preferred variant is multilayer coating with zirconium and chromium and introduction of nitrogen and acetylene (ZrCrCN). Transmission parts coated in this way no longer get stuck or sealed in the implants, not even in case of storage within a liquid. In a PVD process, a combination of chromium and zirconium is vapor-deposited under carbon and nitrogen partial pressure. Initially, ZrN (zirconium nitride) is deposited in alternation with CrN (chromium nitride). In the course of the procedure, the carbon content is increased from 0.5% to up to 60% by addition of acetylene. In total, up to 200 layers are deposited forming a total layer thickness of a few micrometers. The process takes place in high vacuum, and for homogeneous coating the transmission parts are subjected to a triple rotation.

After coating, the elements are taken from the recipient 5 and subjected to subsequent cleaning. The purpose of this cleaning process is first to remove minor impurities stirred up e.g. during aeration of the recipient which can be deposited on the coated elements. Secondly, the surface characteristics of the coating can still be further modified and improved, depending on the selected cleaning agent and method. For the person skilled in the art, it is no problem to select a suitable standard method. It should be taken care, however, that the cleaning agent is biocompatible so that any adhering residues do not cause problems. A water-soluble cleaning agent which makes the surface hydrophilic and dries quickly seems particularly suitable.

The production according to the invention thus comprises a PVD method including the following steps:
precleaning outside the vacuum
positioning the elements in the recipient
application of a vacuum
pretreatment of the titanium or titanium alloy surface by noble gas sputtering
alternating deposition of chromium and zirconium in nitrogen and acetylene atmosphere with constant temperature
linear alteration of the ratio of nitrogen to acetylene
aeration
cleaning with a suitable cleansing bath

The epitaxial growth reduces the tensions within the coating to a minimum, and a high-purity, thin, extremely dense protective layer resistant to wear and corrosion is produced. It can also be sterilized, even under extreme sterilization conditions, yet it will not be possible to observe a particle detachment. The coating has a hardness of 3,600 HV and a measured coefficient of friction dry against steel of 0.18.

The coating according to the invention has a very good layer quality. Strong bonding in the transition or interface zone leads to good adhesion between substrate and coating. This is the prerequisite for a good and permanent adhesion of the coating. In addition, it is important that the coating exhibits low inner tensions which would counteract the bonding or the adhesion. In deposited layers, inner tensions occur as compressive or tensile stresses with forces parallel to the surface for two reasons. First, thermal tensions occur due to different expansion coefficients of the coated part and the coating at different deposition and operating temperatures. Secondly, intrinsic tensions are caused by structural disorder of the foreign and layer atoms. The thermal tensions dominate in low-melting metals; the intrinsic tensions in high-melting metals. A high temperature during deposition encourages the change of place due to volume diffusion and reduces the intrinsic tensions within the layer. In addition, intrinsic tensions can be minimized by the selection of suitable deposition parameters (residual gas pressure, temperature etc.). Intrinsic layer tensions can be reduced by deformation of the layer; however, this can lead to a formation of cracks (with tensile stresses), plastic flow with compressive stresses resulting in formation of bumps and to spalling and delamination of the layer. The layer tensions thus counteract the bonding forces and reduce the adhesion of the layer. To minimize them, several subsequent thin layers of 10 to 50 nm each, alternating between different metals or metal alloys, are deposited with the coating according to the invention. It is a particular advantage if during the PVD procedure a gradient in the carbon content is run. This results in gradual modifications of the composition and thus of the physical properties without sharp alterations and thus to a further reduction of the intrinsic layer tensions.

Another advantage of the coating according to the invention is its biocompatibility. A very good compatibility with tissue and blood has been demonstrated. Therefore, it is suitable to applied to elements used in medical engineering.

By means of the described procedure, the layer thickness can easily be adjusted depending on the area of application. In case of coating of a transmission part mounted on top of a dental implant, a layer thickness of at least 1 μm and at the most 10 μm, more preferably of no more than 5 μm, is recommended.

One of the requirements made on a layer of high quality is the adherence to a precisely defined layer thickness, for the two elements must continue to be manufactured and assembled with precise fit. The thickness also determines the coating properties in terms of unity and hardness. The vapor deposition rate can easily be controlled by means of a quartz crystal oscillator which is coated as well; in addition, the abrasion must be taken into account during sputtering. A high purity of the layer is guaranteed by the purity of the evaporated target material, the preparatory purification steps and the residual gas pressure. Also, good covering of the edges is important in order not to have uncovered places for the process of “cold welding”. This condition is fulfilled by the coating according to the invention as well, particularly due to the fact that coating does not take place with one single layer but with several individual layers. It is therefore to be ensured that the individual layers have good homogeneity.

To test the functionality of the coating according to the invention, a “jamming test” was performed (see Table 1). To this purpose, standard dental implants (Straumann® Standard Plus æ 4.1 mm) made from titanium (ISO 5832-2) were used, transmission parts made from a titanium alloy Ti6AI7Nb (ISO 5832-11) were provided with different coatings. The test was performed with implants assembled in the wet state (150 mM NaCl solution) with the corresponding transmission parts. Then the implants were screwed up to a defined torque into a bone substitute material (Canevasit HGW 2082, version finished by grinding). It was tested whether the transmission part could subsequently be removed without any problems and auxiliary means (excepting predefined securing by means of locking wrench, adapter and ratchet wrench). Even if an implant was screwed in and breakage of the transmission part at the predetermined breaking point was caused artificially at approximately 110 Ncm, it had to be possible to remove the remainder of the transmission part with ease. It had to be possible to remove 90% of the residues without any additional tools. If 10% of the transmission part's residues could be removed with a pair of tweezers (or small pliers) with little application of force, this was still considered operative, since there would be no clinical danger to the patient.

The transmission part in Trial 1 was neither surface-modified nor coated. In Trial 2, the transmission part was electropolished for obtaining a smooth surface in the micro area, electro-polishing is an electrochemical procedure for the polishing of metals. The anodically switched transmission part was provided with counter cathodes and subjected to a DC voltage in a suitable electrolyte. In Trial 3, the surface was altered in the micro area by trovalizing. For this purpose, the transmission parts were placed in a large drum containing special scouring particles. The drum was then rotated for 24 hours; the scouring removed the punching burrs and rounded the edges, on the one hand, and hardened the surface on the other hand. During anodic oxidation in Trials 4 through 6, the surface is anodized (procedure for surface treatment according to DIN 8580). Aluminum was switched as the anode and then electrolyzed in acid by a direct current. Different layer thicknesses were tested; the anodic oxidation coatings have different colors depending on the thickness. During ADLC coating (Trial 8), a pure carbon layer was applied in diamond coordination (sp3) in a CVD procedure. In Trials 9 and 10, a PVD procedure (analogously to the one described above) was performed, however with only one target—one time with pure zirconium, one time with pure titanium; both times with the addition of nitrogen. In Trial 11, tungsten, with the addition of acetylene, was tested as the target. In Trials 12 through 15, the transmission part was coated by the method according to the invention, i.e. with two different metals and with the introduction of acetylene and nitrogen, i.e. ZrCrCN, however with different layer thicknesses between 0.5 and 5.0 μm.

The results of the jamming test are illustrated in Table 1. It shows that only the coating method according to the invention with two different metals solves the problem of cold welding, however only from a layer thickness of 1.0 μm upward.

The invention is now explained in detail by means of an exemplary embodiment.

The following operating and process conditions refer to an exemplary coating procedure for a transmission part using a plant of the type Hauzer 1000-6.

The transmission parts to be coated are added to the recipient or reactor, respectively, in a purified state. Before the coating process is started, the reaction chamber is evacuated to a vacuum of 1×10⁻⁶ mbar, and the substrate is heated to a temperature of approximately 270° C. Before coating is started, the surface of the transmission part to be coated will first be cleaned by ion etching. The following process parameters will be set for this purpose:

Bias: 500-1400 volt
Vaporizer: individually at 60-110 Ah
Running time: 8 s

For the duration of the cleaning process, a turbo-molecular pump runs with full power in order to be able to immediately remove any impurities which might come off during cleaning from the processing chamber. Also, the cleaning process is supported by the addition of very small amounts of argon.

At the beginning of the coating phase, a bias of initially approximately 45 V is applied to the substrate, which bias is reduced in the course of the coating phase to a range of approximately 25-40 V with an increasing percentage of acetylene. During the coating phase, the vaporizer is operated in pulses or continually, the amperage being reduced with increasing acetylene concentration in the course of the coating phase.

During the coating phase, a largely continuous flow of nitrogen in the order of approximately 40 ppm is selected, the acetylene flow at the same time being selected increasing from approximately 0.5—approximately 35%, resulting in approximately 1 to 25-30 ppm, the increase in acetylene flow being preferably set linearly rising. The pressure within the recipient or reaction chamber should be within the range of approximately 5×10⁻³−1×10⁻² mbar, and during the entire coating process, the above-mentioned turbo-molecular pump runs merely with a performance of approximately 60-80%. After coating, the reaction chamber is carefully vented, and the coated transmission parts are subjected to final purification in a standard procedure.

Naturally, the present invention is not limited to the exemplary coatings, coating procedures etc., but the present invention comprises any type of coatings consisting of at least two different metals which, after the application to at least one part made of titanium or titanium alloy, exclude cold welding with mounted assemblies made of at least two elements consisting of titanium or titanium alloy, particularly in case of storage in liquids.

Further, it must be taken into account that elements made of zirconium or zirconium alloys exhibit the cold welding effect similarly to elements made of titanium or titanium alloys. The coating according to the invention is therefore not limited to elements made of titanium or titanium alloys, but can be applied analogously to elements made of zirconium or zirconium alloys in order to solve the problem described above. Thus, methods, elements, coatings and combinations of elements are included in this invention where the elements do not consist of titanium or titanium alloys but of zirconium or zirconium alloys. The above disclosure applies analogously to these methods, elements, coatings and combinations of elements.

TABLE 1

| Trial | Surface modification | Jamming test |
|---|---|---|
| 1 | none | jamming |
| 2 | electro-polishing | jamming |
| 3 | trovalizing | jamming |
| 4 | anodizing blue | jamming |
| 5 | anodizing green | jamming |
| 6 | anodizing yellow | jamming |
| 7 | anodizing magenta | jamming |
| 8 | ADLC | jamming |
| 9 | titanium nitride | jamming |
| 10 | zirconium nitride | jamming |
| 11 | tungsten carbide | jamming |
| 12 | ZrCrCN with a layer thickness of | jamming |
| | 0.5 μm | |
| 13 | ZrCrCN with a layer thickness of | no jamming |
| | 1.0 μm | |
| 14 | ZrCrCN with a layer thickness of | no jamming |
| | 2.5 μm | |
| 15 | ZrCrCN with a layer thickness of | no jamming |
| | 5.0 μm | |

What is claimed is:

1-16. (canceled)

17. PVD method for coating elements made of titanium or titanium alloy, or zirconium or zirconium alloy, respectively, including at least the following steps:
a) positioning the elements in a recipient,
b) application of a vacuum,
c) deposition of a first metal in nitrogen and acetylene atmosphere,
d) deposition of a second metal in nitrogen and acetylene atmosphere,
e) repetition of steps c) and d) until a layer thickness of 1 μm is achieved,
f) ventilation of the recipient,
g) removal of the elements from the recipient,
h) purification of the elements with a suitable cleansing bath, wherein the first metal is chromium and the second metal is zirconium.

18. Method according to claim 17, wherein after step b), a pretreatment of the surface is performed, in particular by sputtering with noble gases.

19. Method according to claim 18, wherein during step e), the ratio of nitrogen and/or acetylene is altered.

20. Method according to claim 19, wherein the alteration is linear.

21. Method according to claim 17, wherein more than two metals or metal alloys are deposited.

22. Method according to claim 18, wherein more than two metals or metal alloys are deposited.

23. Method according to claim 19, wherein more than two metals or metal alloys are deposited.

24. Element made of titanium or titanium alloy, having a coating manufactured with a method according to claim 17.

25. Element according to claim 24, being an implant, a dental implant, a bone screw or a transmission part.

26. Coating on an element made of titanium or titanium alloy, or zirconium or zirconium alloy, respectively, produced with a method according to claim 17.

27. Coating according to claim 26, wherein the amount of the first metal or the first metal alloy in comparison to the total amount of metal in the coating is between 30 and 70 atomic percent, in particular between 40 and 60 atomic percent, particularly preferred between 45 and 55 atomic percent.

28. Combination of elements where at least one element is at least partially provided with a coating according to claim 26.

29. Combination of elements where at least one element is at least partially provided with a coating according to claim 26.
